(19) United States
(12) Patent Application Publication
(10) Pub. No.: US 2025/0117306 A1
(43) Pub. Date: Apr. 10, 2025

(54) SYNCHRONOUS SIMULATION OF ASYNCHRONOUS RUNTIME DATA OF AUTONOMOUS DRIVING

(71) Applicant: TuSimple, Inc., SAN DIEGO, CA (US)

(72) Inventors: Dantong DONG, San Diego, CA (US); Ao LIU, San Diego, CA (US); Jing MA, Evanston, IL (US); Yixin YANG, San Diego, CA (US); Yuxuan LUO, Charlotte, NC (US)

(21) Appl. No.: 18/905,961

(22) Filed: Oct. 3, 2024

Related U.S. Application Data
(60) Provisional application No. 63/589,224, filed on Oct. 10, 2023.

(51) Int. Cl. G06F 11/34; G06F 11/36

(52) U.S. Cl. CPC G06F 11/3457; G06F 11/3612; G06F 11/3698

(57) ABSTRACT

Devices, systems, and methods for simulating an operation of an autonomous vehicle over time are described. An example method includes obtaining runtime data of an operation of modules of an autonomous vehicle during the operation, the runtime data including first module data having a first refresh frequency and second module data having a second refresh frequency, compiling a plurality of simulation data packets based on the runtime data according to a simulation frequency that is different from at least one of the first refresh frequency or the second refresh frequency, and simulating the operation of the autonomous vehicle over time based on the plurality of simulation data packets.

### CROSS-REFERENCE TO RELATED APPLICATIONS

This document claims priority to and the benefit of U.S. Provisional Application No. 63/589,224, filed on Oct. 10, 2023. The aforementioned application of which is incorporated herein by reference in its entirety.

### TECHNICAL FIELD

This document generally relates to simulation systems and methods, and more specifically, systems and methods for synchronous simulation of asynchronous runtime data of autonomous driving.

### BACKGROUND

Autonomous vehicle navigation is a technology for sensing the position and movement of a vehicle and, based on the sensing, autonomously control the vehicle to navigate towards a destination. Autonomous vehicle control and navigation can have important applications in transportation of people, goods and services. Efficiently generating commands for the powertrain of a vehicle that enable its accurate control is paramount for the safety of the vehicle and its passengers, as well as people and property in the vicinity of the vehicle, and for the operating efficiency of driving missions.

### SUMMARY

Aspects of the present document relates to devices, systems, and methods for simulating an operation of an autonomous vehicle.

One aspect of the present document relates to an example method for simulating an operation of an autonomous vehicle over time. The example method includes: obtaining runtime data of the operation of the autonomous vehicle (AV) during the operation, the runtime data including first module data having a first refresh frequency and second module data having a second refresh frequency, wherein: the first module data includes a plurality of first module data units, each of the plurality of first module data units having a first timestamp that relates to the first refresh frequency and indicates a first acquisition time; and the second module data includes a plurality of second module data units, each of the plurality of second module data units having a second timestamp that relates to the second refresh frequency and indicates a second acquisition time; compiling a plurality of simulation data packets based on the runtime data according to a simulation frequency that is different from at least one of the first refresh frequency or the second refresh frequency, wherein each of the plurality of simulation data packets comprises or relates to: a simulation timestamp that relates to the simulation frequency and indicates a sampling time; a first module data unit corresponding to a first timestamp, a first time interval between the first acquisition time and the sampling time being below a first threshold relating to the first refresh frequency; and a second module data unit corresponding to a second timestamp, a second time interval between the second acquisition time and the sampling time being below a second threshold relating to the second refresh frequency; and simulating the operation of the autonomous vehicle over time based on the plurality of simulation data packets.

One aspect of the present document relates to an example method for simulating an event over time. One aspect of the present document relates to an example system including memory storing computer program instructions; and one or more processors configured to execute the computer program instructions to effectuate the simulation method as described herein.

One aspect of the present document relates to an example system for simulating an operation of an autonomous vehicle over time. The example system includes a distiller module configured to: receive runtime data, the runtime data comprising first module data having a first refresh frequency and second module data acquired at a second refresh frequency, wherein the first module data comprises a plurality of first module data units, each of the plurality of first module data units having a timestamp that relates to the first refresh frequency and indicates a first acquisition time when the first module data unit was acquired; and the second module data comprises a plurality of second module data units, each of the second module data units having a timestamp that relates to the second refresh frequency and indicates a second acquisition time when the second module data unit was acquired; a temporal call procedure manager configured to compile, based on the runtime data, a plurality of simulation data packets according to a simulation frequency that is different from at least one of the first refresh frequency or a second refresh frequency, wherein each of the plurality of simulation data packets comprises or relates to: a timestamp that relates to the simulation frequency and indicates a sampling time; a first module data unit corresponding to a first timestamp, a first time interval between the first timestamp and the sampling time being below a first threshold relating to the first refresh frequency; and a second module data unit corresponding to a second timestamp, a second time interval between the second timestamp and the sampling time being below a second threshold relating to the second refresh frequency; and an assembler configured to simulate the operation of the autonomous vehicle over time based on the plurality of simulation data packets.

The above and other aspects and features of the disclosed technology are described in greater detail in the drawings, the description, and the claims.

### BRIEF DESCRIPTION OF THE DRAWINGS

FIG. 1 illustrates a block diagram of an example vehicle ecosystem according to some embodiments of the present document.

FIG. 2 illustrates a block diagram of a simulation system according to some embodiments of the present document.

FIGS. 3A through 3D illustrate compiling synchronous simulation data packets based on asynchronous runtime data according to different simulation frequencies according to some embodiments of the present document.

FIG. 4 illustrates an example of a hardware platform that can implement some methods and techniques described in the present document.

FIG. 5 illustrates a flowchart of a process for simulating an operation of an autonomous vehicle according to some embodiments of the present document.

FIGS. 6 and 7 illustrate use cases of the simulation technology according to some embodiments of the present document.

### DETAILED DESCRIPTION

The transportation industry has been undergoing considerable changes in the way technology is used to control the operation of vehicles. As exemplified in the automotive passenger vehicle, there has been a general advancement towards shifting more of the operational and navigational decision making away from the human driver and into on-board computing power. This is exemplified in the extreme by the numerous under-development autonomous vehicles. Current implementations are in intermediate stages, such as the partially-autonomous operation in some vehicles (e.g., autonomous acceleration and navigation, but with the requirement of a present and attentive driver), the safety-protecting operation of some vehicles (e.g., maintaining a safe following distance and automatic braking), the safety-protecting warnings of some vehicles (e.g., blind-spot indicators in side-view mirrors and proximity sensors), as well as ease-of-use operations (e.g., autonomous parallel parking).

Different types of autonomous vehicles have been classified into different levels of automation under the Society of Automotive Engineers' (SAE) J3016 standard, which ranges from Level 0 in which the vehicle has no automation to Level 5 (L5) in which the vehicle has full autonomy. In an example, SAE Level 4 (L4) is characterized by the vehicle operating without human input or oversight but only under select conditions defined by factors such as road type or geographic area. In order to achieve SAE L4 autonomy, vehicle control commands must be efficiently computed while collaborating with both the high-level mission planner and the low-level powertrain characteristics and capabilities.

The control of autonomous vehicles is a complicated task, involving coordination of multiple modules of an autonomous driving system. Such an autonomous driving system needs to be tested rigorously before implementation, and may be updated when more information (e.g., runtime data from road trips), new hardware (e.g., sensors), or the like, or a combination thereof, becomes available. For example, when more road tests are performed from which more runtime data becomes available, algorithms of one or more software modules may be improved with respect to, e.g., object detection, handling of various traffic and/or weather conditions, handling of edge cases, or the like, or a combination thereof. As another example, when better hardware (e.g., sensors with better temporal and/or spatial resolution, processors with improved computational capacities, faster data transmission within the system, more powerful powertrain, etc.) becomes available and/or computationally/commercially feasible, one or more software modules may need to be adjusted accordingly. In some cases, it is expensive, dangerous, and/or infeasible to robustly test an autonomous driving system in real-world driving environments. Instead, simulators can be used.

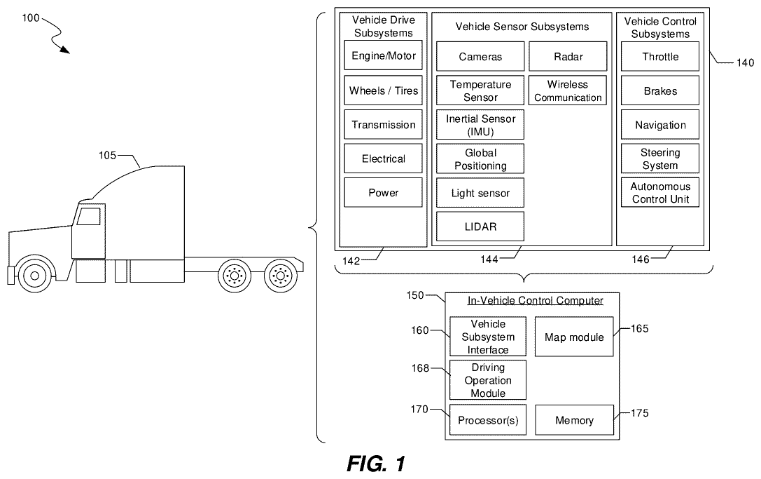

Most autonomous driving or Advanced Driver Assistance Systems (ADAS) systems use asynchronized call pattern in runtime to provide robustness and fast response. For example, an autonomous driving system of an autonomous vehicle (also referred to an ego) may include a perception module, a detection module, a tracking module, a prediction module, a planning module, a control module, or the like, or a combination thereof. The perception module (e.g., vehicle sensor subsystems 144 as illustrated in FIG. 1) may be configured to gather perception data from the real world driving environment. The detection module may be configured to detect an object (e.g., a vehicle (also referred to as a non-player character or NPC), a pedestrian, an obstacle) based on sensor data acquired by one or more ego sensors (e.g., an image captured by a camera on the ego) in a time frame in the real world driving environment. The tracking module may be configured to track an object over a period of time based on sensor data acquired by one or more ego sensors (e.g., a series of images acquired over multiple time frames by one or more cameras on the ego). The prediction module may be configured to predict the trajectory of an object in a vicinity of the ego (e.g., an object detected by the detection module, an object detected by the tracking module). The planning module may be configured to generate a trajectory for the ego based on the environment around the ego and the destination of the ego. The control module (e.g., vehicle control subsystems 140 as illustrated in FIG. 1 may be configured to generate control commands or for controlling the operation of components of the engine domain (e.g., vehicle drive subsystems 142 as illustrated in FIG. 1) of the ego including, e.g., the powertrain, the brake, etc.

Various modules may operate at various refresh frequencies. Merely by way of example, the perception module may operate at a perception refresh frequency of 10 Hz; the control module may operate at a control refresh frequency of 100 Hz. Additionally, or alternatively, in operation, random events may introduce random asynchronicity into the system. For example, a perception module of an autonomous vehicle may normally operate at a perception refresh frequency of 10 Hz; an unexpected delay (e.g., a delay of 0.1 milliseconds in the transmission of a sensor data unit acquired in a time frame) in the transmission of perception data within the system may introduce random asynchronicity in the perception data itself with respect to data of other modules of the system, and such asynchronicity may propagate within the system.

Asynchronized call pattern may be hard to reproduce in an offline run such as simulation due to the inherent nature of asynchronicity, which is dependent on systematic and/or random/unreproducible environment variables as described above. Existing simulation methods either simulate asynchronously as runtime, which discard reproducibility, or simulate synchronously, which discard realism. This document describes systems and methods for synchronized simulation to reproduce an asynchronized runtime behavior to address these and other technical challenges or problems.

Some embodiments of the present document include systems and methods for simulating an operation of an autonomous vehicle (AV). In some embodiments, the simulation system may include a node distiller, a temporal call procedure manager, an external caller, and an assembler. The node distiller may be configured to organize node (also referred to as module) data of various nodes into data units labelled with temporal timestamps. The nodes may have their respective refresh frequencies. At least two of the nodes may have different refresh frequencies and accordingly are asynchronous. The timestamps of data units of a node data may relate to the refresh frequency of the node. The temporal call procedure manager may be configured to synthesize the node data into a single call pattern for each simulation frame duration (determined by a specified simulation frequency). The call pattern may generate a simulation data packet for each simulation frame duration. A simulation data packet may correspond to a sampling time that relates to the simulation frequency. A simulation data packet may include or relate to a data unit of each of the various nodes that are retrieved based on the sampling time of the simulation data packet. The external caller may be configured to take data units of one or more of the various nodes generated from call procedure manager and communicate with corresponding external algorithm node(s) to produce runtime data. The produced runtime data may be collected by the call procedure manager. The assembler may be configured to assemble the produced runtime data forwarded by the call procedure manager and convert them to AV (also referred to as ego) information and return it to the system, thereby achieving a synchronized simulation to reproduce an asynchronized runtime environment. The simulation technology as described may allow developers to better recreate runtime results for developing and debugging various software components of the autonomous driving system and/or the simulation system itself. This simulation technology as described can also allow the testing of frequency synthetization offline. The simulation technology may be implemented using a lightweight plug-in to an existing simulation system.

The versatility of the simulation technology lies in its ability to process diverse inputs and generate corresponding outputs, making it suitable for various applications across different domains. The simulation technology can take asynchronized runtime data as input and generate, based on synchronized simulation data packets, a reproducible simulation data as output, thereby solving the reproducibility issue in asynchronized simulation. The simulation technology can take a simulation frequency configuration as input and generate an asynchronized runtime data (including, e.g., node data of various nodes having different refresh frequencies) for frequency testing as output, thereby allowing frequency tuning in an offline environment. The following description is provided with reference to an autonomous vehicle for illustration purposes and not intended to be limiting. The simulation technology as described can be applied to not only ADAS but also reproduction or simulation of other behavior or events that include asynchronized components.

FIG. 1 illustrates a block diagram of an example vehicle ecosystem according to some embodiments of the present disclosure. The system 100 may include an autonomous vehicle 105, such as a tractor unit of a semi-trailer truck. The autonomous vehicle 105 may include a plurality of vehicle subsystems 140 and an in-vehicle control computer 150. The plurality of vehicle subsystems 140 can include, for example, vehicle drive subsystems 142, vehicle sensor subsystems 144, and vehicle control subsystems 146. FIG. 1 shows several devices or systems being associated with the autonomous vehicle 105. In some embodiments, additional devices or systems may be added to the autonomous vehicle 105, and in some embodiments, some of the devices or systems shown in FIG. 1 may be removed from the autonomous vehicle 105.

An engine/motor, wheels and tires, a transmission, an electrical subsystem, and/or a power subsystem may be included in the vehicle drive subsystems 142. The engine/motor of the autonomous truck may be an internal combustion engine (or gas-powered engine), a fuel-cell powered electric engine, a battery powered electric engine/motor, a hybrid engine, or another type of engine capable of actuating the wheels on which the autonomous vehicle 105 (also referred to as vehicle 105 or autonomous truck 105) moves. The engine/motor of the autonomous vehicle 105 can have multiple engines to drive its wheels. For example, the vehicle drive subsystems 142 can include two or more electrically driven motors.

The transmission of the vehicle 105 may include a continuous variable transmission or a set number of gears that translate power created by the engine of the vehicle 105 into a force that drives the wheels of the vehicle 105. The vehicle drive subsystems 142 may include an electrical system that monitors and controls the distribution of electrical current to components within the vehicle drive subsystems 142 (and/or within the vehicle subsystems 140), including pumps, fans, actuators, in-vehicle control computer 150 and/or sensors (e.g., cameras, light detection and ranging LiDARs, RADARs, etc.). The power subsystem of the vehicle drive subsystems 142 may include components which regulate a power source of the vehicle 105.

Vehicle sensor subsystems 144 can include sensors which are used to support general operation of the autonomous truck 105. The sensors for general operation of the autonomous vehicle may include, for example, one or more cameras, a temperature sensor, an inertial sensor, a global positioning system (GPS) receiver, a light sensor, a LiDAR system, a radar system, and/or a wireless communications system.

The vehicle control subsystems 146 may include various elements, devices, or systems including, e.g., a throttle, a brake unit, a navigation unit, a steering system, and an autonomous control unit. The vehicle control subsystems 146 may be configured to control operation of the autonomous vehicle, or truck, 105 as a whole and operation of its various components. The throttle may be coupled to an accelerator pedal so that a position of the accelerator pedal can correspond to an amount of fuel or air that can enter the internal combustion engine. The accelerator pedal may include a position sensor that can sense a position of the accelerator pedal. The position sensor can output position values that indicate the positions of the accelerator pedal (e.g., indicating the amount by which the accelerator pedal is actuated).

The brake unit can include any combination of mechanisms configured to decelerate the autonomous vehicle 105. The brake unit can use friction to slow the wheels of the vehicle in a standard manner. The brake unit may include an anti-lock brake system (ABS) that can prevent the brakes from locking up when the brakes are applied. The navigation unit may be any system configured to determine a driving path or route for the autonomous vehicle 105. The navigation unit may additionally be configured to update the driving path dynamically based on, e.g., traffic or road conditions, while, e.g., the autonomous vehicle 105 is in operation. In some embodiments, the navigation unit may be configured to incorporate data from a GPS device and one or more predetermined maps so as to determine the driving path for the autonomous vehicle 105. The steering system may represent any combination of mechanisms that may be operable to adjust the heading of the autonomous vehicle 105 in an autonomous mode or in a driver-controlled mode of the vehicle operation.

The autonomous control unit may include a control system (e.g., a computer or controller comprising a processor) configured to identify, evaluate, and avoid or otherwise negotiate potential obstacles in the environment of the autonomous vehicle 105. In general, the autonomous control unit may be configured to control the autonomous vehicle 105 for operation without a driver or to provide driver assistance in controlling the autonomous vehicle 105. In some example embodiments, the autonomous control unit may be configured to incorporate data from the GPS device, the radar, the LiDAR, the cameras, and/or other vehicle sensors and subsystems to determine the driving path or trajectory for the autonomous vehicle 105.

An in-vehicle control computer 150, which may be referred to as a vehicle control unit or VCU, can include, for example, any one or more of: a vehicle subsystem interface 160, a map data sharing module 165, a driving operation module 168, one or more processors 170, and/or memory 175. This in-vehicle control computer 150 may control many, if not all, of the operations of the autonomous truck 105 in response to information from the various vehicle subsystems 140. The memory 175 may contain processing instructions (e.g., program logic) executable by the processor(s) 170 to perform various methods and/or functions of the autonomous vehicle 105, including those described in this patent document. For instance, the data processor 170 executes the operations associated with vehicle subsystem interface 160, map data sharing module 165, and/or driving operation module 168. The in-vehicle control computer 150 can control one or more elements, devices, or systems in the vehicle drive subsystems 142, vehicle sensor subsystems 144, and/or vehicle control subsystems 146. For example, the driving operation module 168 in the in-vehicle control computer 150 may operate the autonomous vehicle 105 in an autonomous mode in which the driving operation module 168 can send instructions to various elements or devices or systems in the autonomous vehicle 105 to enable the autonomous vehicle to drive along a determined trajectory. For example, the driving operation module 168 can send instructions to the steering system to steer the autonomous vehicle 105 along a trajectory, and/or the driving operation module 168 can send instructions to apply an amount of brake force to the brakes to slow down or stop the autonomous vehicle 105.

The map data sharing module 165 can be also configured to communicate and/or interact via a vehicle subsystem interface 160 with the systems of the autonomous vehicle. The map data sharing module 165 can, for example, send and/or receive data related to the trajectory of the autonomous vehicle 105 as further explained in Section II. The vehicle subsystem interface 160 may include a software interface (e.g., application programming interface (API)) through which the map data sharing module 165 and/or the driving operation module 168 can send or receive information to one or more devices in the autonomous vehicle 105.

The memory 175 may include instructions to transmit data to, receive data from, interact with, or control one or more of the vehicle drive subsystems 142, vehicle sensor subsystems 144, or vehicle control subsystems 146. The in-vehicle control computer (VCU) 150 may control the operation of the autonomous vehicle 105 based on inputs received by the VCU from various vehicle subsystems (e.g., the vehicle drive subsystems 142, the vehicle sensor subsystems 144, and the vehicle control subsystems 146). The VCU 150 may, for example, send information (e.g., commands, instructions or data) to the vehicle control subsystems 146 to direct or control functions, operations or behavior of the autonomous vehicle 105 including, e.g., its trajectory, velocity, steering, braking, and signaling behaviors. The vehicle control subsystems 146 may receive a course of action to be taken from one or more modules of the VCU 150 and may, in turn, relay instructions to other subsystems to execute the course of action.

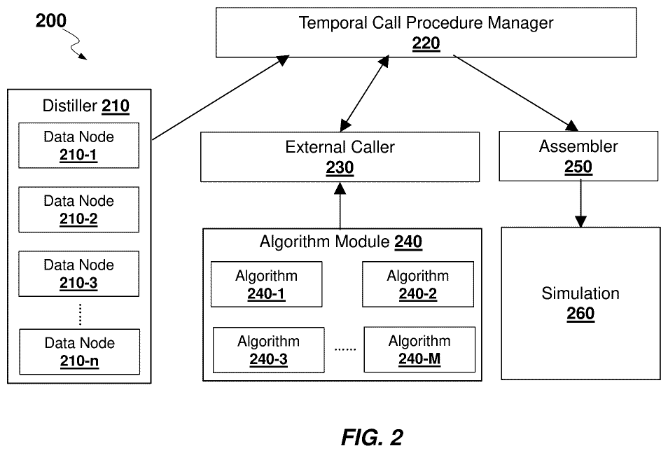

FIG. 2 illustrates a block diagram of an example simulation system according to some embodiments of the present disclosure. The simulation system 200 may include a distiller 210, a temporal call procedure manager 220, an external caller 230, an algorithm module 240, an assembler 250, and a simulation module 260. In some embodiments, the simulation system 200 (without controlling the vehicle drive subsystems 142 to effectuate an actual operation of an autonomous vehicle) may function in a similar manner as the VCU 150 except that the simulation system 200 is flexible in terms of input and output the simulation system 200 can take and allows more freedom to configure components of the simulation system 200. For example, the simulation system 200 may receive runtime data recording an operation (e.g., a road test) of an autonomous vehicle and simulate the operation based on at least a portion of the runtime data. As another example, the simulation system 200 may allow configuration or testing of a refresh frequency of a component (e.g., a sensor, a planning module, a prediction module), an algorithm or software module in an offline mode.

The distiller 210 may be configured to receive runtime data of an operation (e.g., a road test) of an autonomous vehicle. The runtime data may include data from various components involved in autonomous driving of the autonomous vehicle. For example, the runtime data may include sensor data from one or more sensors of the perception module (e.g., the vehicle sensor subsystems 144 as illustrated in FIG. 1), detection data from the detection module, tracking data from the tracking module, planning data from the planning module, control data from the control module (e.g., the vehicle control subsystems 140 as illustrated in FIG. 1), or the like, or a combination thereof. Data obtained from a module or sensor may be referred to as module data. The distiller 210 may include multiple data nodes, 210-1, 210-2, 210-3, . . . 210-n. Different data nodes may be configured to store module data from different modules. Data from different sensors of the perception module (e.g., the vehicle sensor subsystems 144 as illustrated in FIG. 1) may be stored in different data nodes. Merely by way of example, the perception module may include camera 1, camera 2, and a LiDAR sensor; camera 1 image data may be stored in data node 210-1, camera 2 image data in data node 210-2, the LiDAR sensor data in data node 210-3. By organizing data from different sensors or modules in different data nodes, a user or a software module (e.g., the algorithm module 240) can access relevant data.

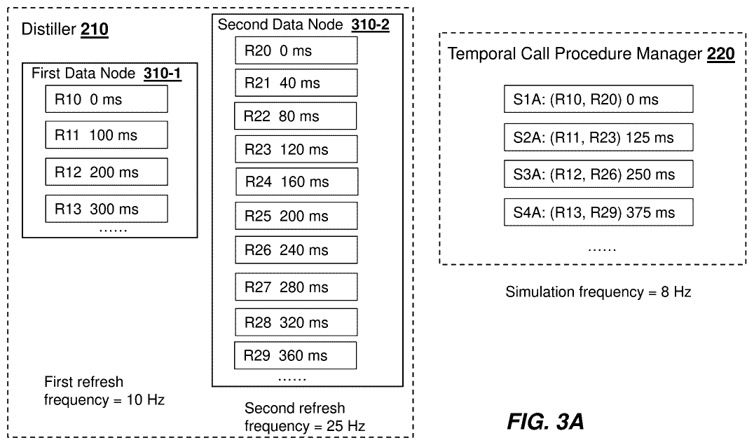

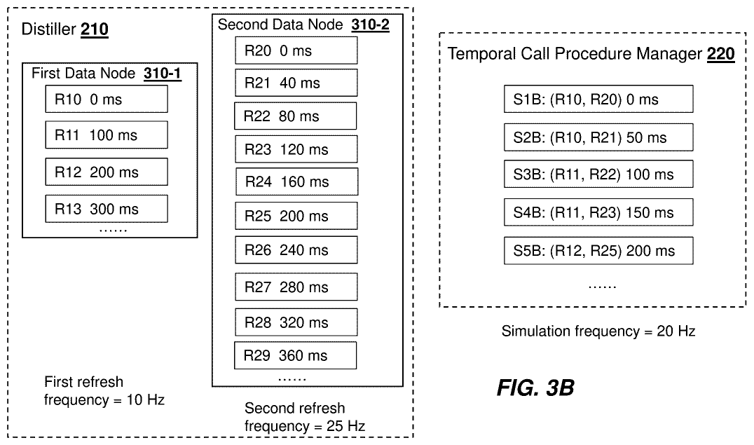

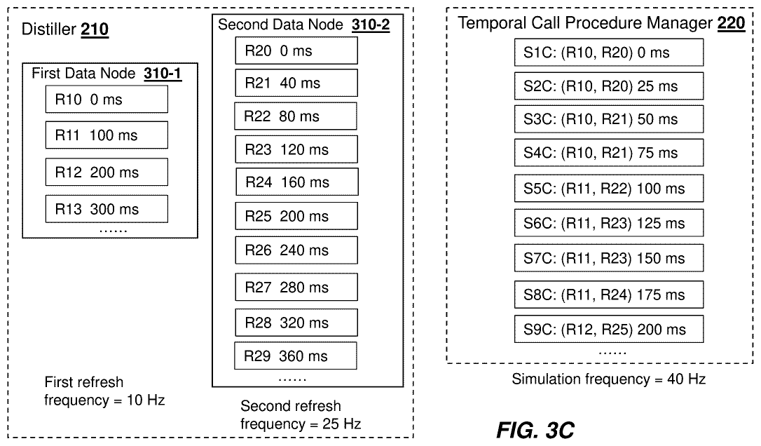

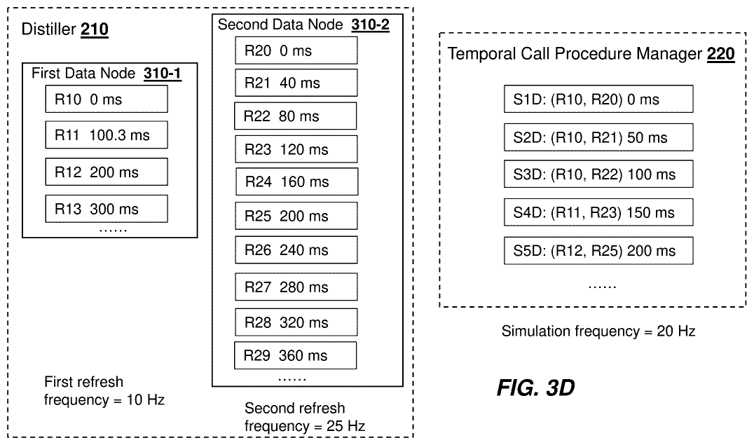

At least two of the modules may operate at different refresh frequencies. Merely by way of example, one or more sensors of the perception module may acquire data at a refresh frequency of 10 Hz, the planning module may operate at a refresh module of 10 Hz; the control module may operate at a refresh module of 50 Hz. Accordingly, the runtime data may be asynchronous. FIGS. 3A through 3D illustrate asynchronous runtime data including first module data having a first refresh frequency of 10 Hz and second module data having a second refresh frequency of 25 Hz.

In some embodiments, the asynchronous operations of at least two of the modules may be achieved by controlling the modules using different clock sources or clock signals. The different clock sources or clock signals may be generated by software, hardware, or a combination thereof. Merely by way of example, the different sources or clock signals may be generated by different clocks that are configured to operate independently.

The distiller 210 may be configured to organize module data in each of the data nodes 210-1 through 210-n based on the respective refresh frequencies. In some embodiments, the module data of a data node may be organized as data units each of which may include data acquired or generated within the time frame of one update of the module. Each data unit may be labeled with a timestamp that indicates the time data of the data unit is acquired or generated. Accordingly, the timestamps of the data units of module data may correspond to the refresh frequency of the module. For example, the data node 210-1 stores camera 1 image data. In some embodiments, a timestamp may deviate from an expected or ideal time data of a data unit should have been acquired or generated based on the refresh frequency. Such a deviation may be due to, e.g., a delay in the transmission of the data to or within the simulation system 200 (e.g., sensor data from a sensor where the sensor data is acquired to the corresponding storage in the perception module, or a downstream module), a glitch in processing the data (e.g., a glitch in data processing in the control module), or the like, or a combination thereof. Such deviation may be recorded in the timestamp.

The temporal call procedure manager 220 may be configured to synthesize the node data into a single call pattern for each simulation frame duration (determined by specified simulation frequency). Such a call pattern may generate, based on the runtime data organized in the distiller 210, a plurality of simulation data units. Each of the plurality of simulation data units may correspond to a simulation frame duration determined based on the simulation frequency. Each of the plurality of simulation data units may be labelled with a simulation timestamp that indicates a sampling time determined based on the simulation frequency. According to the call pattern, the asynchronous runtime data may be arranged as synchronous simulation data units having the simulation frequency.

FIGS. 3A through 3D illustrate compiling synchronous simulation data packets based on asynchronous runtime data according to different simulation frequencies according to some embodiments of the present document. First data node 310-1 includes data from a first module operating at a first refresh frequency of 10 Hz. The first module data are organized as first module data units R1i (i is an integer) according to the first refresh frequency. The first module data units R1i are labeled with timestamps that relates to the first refresh frequency and indicate when data of the data units are acquired or determined. Second data node 310-2 includes data from a second module operating at a second refresh frequency of 25 Hz. The second module data are organized as second module data units R2i (i is an integer) according to the second refresh frequency. The second module data units R2i are labeled with timestamps that relates to the second refresh frequency and indicate when data of the data units are acquired or determined. R10 and R20 corresponding to an acquisition time of 0 ms may be acquired by an actual measurement (e.g., by a sensor) or data processing (e.g., determined based on sensor data) or assigned (e.g., as part of an initiation process of the autonomous driving system performed to prepare the autonomous vehicle for a road trip).

FIGS. 3A through 3D illustrate asynchronous runtime data including first module data having a first refresh frequency of 10 Hz and second module data having a second refresh frequency of 25 Hz. FIGS. 3A through 3C illustrates simulation data packets having simulation frequencies of 8 Hz, 20 Hz, and 40 Hz, respectively, according to some embodiments of the present document.

According to the call pattern, the temporal call procedure manager 220 may be configured to call data units of various modules based on the sampling times and the timestamps of the data units in the distiller 210. With reference to FIGS. 3A though 3C, to generate a simulation data packet corresponding to a sampling time, the temporal call procedure manager 220 may identify a first module data unit from the plurality of first module data units and a second module data unit from the plurality of second module data units; the identified first module data unit has a first timestamp that is no later than the sampling time; and the identified second module data unit has a second timestamp that is no later than the sampling time. Merely by way of example, the identified first module data unit has a first timestamp that is no later than and closest to the sampling time among the plurality of first module data units; and the identified second module data unit has a second timestamp that is no later than and closet to the sampling time among the plurality of second module data units; accordingly, the retrieved first data unit or the second data unit may the most recent module data unit available at the sampling time. The simulation frequency may be different from at least one of the first refresh frequency or the second refresh frequency. For example, the simulation frequency may be lower than the lower of the first refresh frequency and the second refresh frequency. As another example, the simulation frequency may fall between the first refresh frequency and the second refresh frequency. As a further example, the simulation frequency may be higher than the higher of the first refresh frequency and the second refresh frequency.

As illustrated in FIG. 3A where the simulation frequency is 8 Hz, the sampling times for the simulation data packets may be set accordingly and with reference to the times when the first module data and the second module data are acquired or determined. For example, the sampling times may be 0 milliseconds (ms), 125 ms, 250 ms, 375 ms, . . . . For a simulation data packet S1A corresponding to the sampling time of 0 ms, the temporal call procedure manager 220 may retrieve a first module data unit from the first data node 310-1 based on the sampling time and the timestamps of the first module data units. The retrieved first data unit may be the one whose timestamp is no later than and closest to the sampling time of 0 ms among the plurality of first module data units that is R10. Accordingly, the retrieved first data unit is the most recent first module data unit available at the sampling time. Similarly, the temporal call procedure manager 220 may retrieve a second module data unit from the second data node 310-2 based on the sampling time of 0 ms and the timestamps of the second module data units. The retrieved second data unit may be the one whose timestamp is no later than and closest to the sampling time of 0 ms among the plurality of second module data units, that is R20. Accordingly, the retrieved first data unit is the most recent first module data unit available at the sampling time. The simulation data packet S1A may include or relate to 10 and R20, and be labeled with a simulation timestamp of 0 ms. Following this call pattern, the temporal call procedure manager 220 may compile the simulation data packets S1A, S2A, S3A, S4A, . . . , as illustrated in FIG. 3A. Similarly, the temporal call procedure manager 220 may compile the simulation data packets S1B, S2B, S3B, S4B, S5B, . . . , as illustrated in FIG. 3B according to a simulation frequency of 20 Hz; the temporal call procedure manager 220 may compile the simulation data packets S1C, S2C, S3C, . . . , as illustrated in FIG. 3C according to a simulation frequency of 40 Hz. Accordingly, the first module data and the second module data that are asynchronous are compiled into simulation data packets in a synchronous manner.

FIG. 3D illustrates runtime data that is similar to what is illustrated in FIG. 3B except that the acquisition time of the first module data unit R11, 100.3 ms, deviates from the expected acquisition time of 100 ms by 0.3 ms. When the temporal call procedure manager 220 compiles the simulation data packets at the simulation frequency of 20 Hz, R11 is not assigned to the simulation data packet S3D corresponding to the sampling time of 100 ms; instead, R10 acquired at 0 ms, which is the most recent first module data unit available at the sampling time of 100 ms, is assigned the simulation data packet S3D. Accordingly, asynchronicity introduced by random events may be represented or reproduced in the simulation data packets in a synchronous and (also predictable) manner.

In some embodiments, for two simulation data packets corresponding to two consecutive sampling times, first module data units of the two simulation data packets have a same first timestamp, and second module data units of the two simulation data packets have a same second timestamp. See, e.g., S1C vs. S2C, S3C vs. S4C, and S6C vs. S7C, as illustrated in FIG. 3C. In some embodiments, for two simulation data packets corresponding to two consecutive sampling times, first module data units of the two simulation data packets have a same first timestamp, and second module data units of the two simulation data packets have different second timestamps. See, e.g., S1B vs. S2B, and S3B vs. S4B as illustrated in FIG. 3B, S2C vs. S3C, and S5C vs. S6C as illustrated in FIG. 3C, S1D vs. S2D, and S2D vs. S3D as illustrated in FIG. 3D. In some embodiments, for two simulation data packets corresponding to two consecutive sampling times, first module data units of the two simulation data packets have different first timestamps, and second module data units of the two simulation data packets have different second timestamps. See, e.g., S1A vs. S2A, and S2A vs. S3A as illustrated in FIG. 3A, S2B vs. S3B, and S4B vs. S5B as illustrated in FIG. 3B, S4C vs. S5C, and S8C vs. S9C as illustrated in FIG. 3C, S3D vs. S4D, and S4D vs. S5D as illustrated in FIG. 3D.

In some embodiments, the simulation system 200 may simulate the runtime data form a same operation of the autonomous vehicle based on different simulation frequencies and compare simulated results obtained based on such different simulation frequencies. In some embodiments, the simulation system 200 may receive, e.g., via a user interface, a user instruction regarding the simulation frequency and configure the simulation frequency based on the user instruction.

In some embodiments, at least some of the data units retrieved from the distiller 210 may remain in the simulation data packets as is for one or more subsequent steps of the simulation procedure in the simulation system 200. For example, data units from the control module of the autonomous vehicle may remain as is in the simulation data packets and are used for assessing a control instruction generated by simulation. In some embodiments, at least some of the data units retrieved from the distiller 210 may be processed before used in subsequent portion of the simulation procedure in the simulation system 200. For example, data units from a sensor of the perception module of the autonomous vehicle in the simulation data packets may be processed before used in subsequent portion of the simulation procedure.

Returning to FIG. 2, the external caller 230 may be configured to process at least a portion of the simulation data packets to produce simulated runtime data before they are used in subsequent portion of the simulation procedure in the simulation system 200. The external caller 230 may retrieve simulation data packets from the temporal call procedure manager 220, and call algorithm module 240 to obtain applicable processing algorithms, and process at least a portion of the data units in the simulation data packets using the applicable processing algorithms. For example, the algorithm module 240 has algorithms 240-1 configured to process the first module data, 240-2 configured to process the second module data, 240-3 configured to process a third module data, . . . 240-M configured to process a module data M. The external caller 230 may retrieve simulation data packets (e.g., S1A, S2A, S3A, . . . as illustrated in FIG. 3A, or S1B, S2B, S3B, . . . as illustrated in FIG. 3B, or S1C, S2C, S3C, . . . as illustrated in FIG. 3C) from the temporal call procedure manager 220, in which each simulation data packet includes a first module data unit and a second module data unit. The external caller 230 may call the algorithm module 240 and retrieve algorithms 240-1 and 240-2 and for each of the retrieved simulation data units, process the first module data unit using the algorithm 240-1, and process the second module data unit using the algorithm 240-2. The external caller 230 may return to the temporal call procedure manager 220 the simulated runtime data organized as the simulation data packets. Each of the simulation data packets may include a processed first module data unit and a processed second module data unit.

In some embodiments, the externa caller 230 may keep the initial first or second module data units retrieved from the distiller 210 in the simulation data packets, and add the processed first or second module data units to the corresponding simulation data packets; accordingly, the external caller 230 may return to the temporal call procedure manager 220 simulation data packets that include both the initial first or second module data units and their processed counterparts. In some embodiments, the externa caller 230 may replace the initial first or second module data units retrieved from the distiller 210 in the simulation data packets with their processed counterparts; accordingly, the external caller 230 may return to the temporal call procedure manager 220 simulation data packets that include the processed first or second module data units but not the initial first or second module data units.

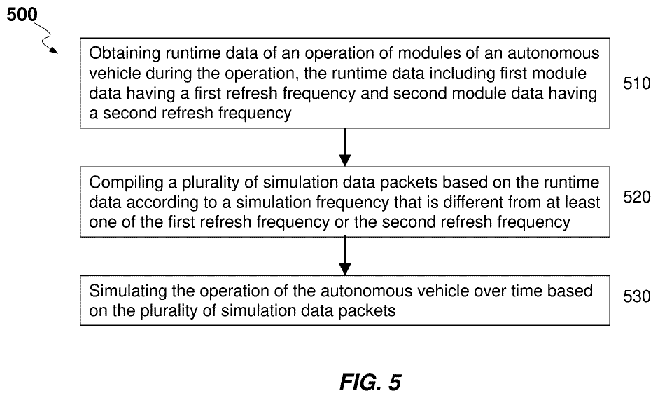

The temporal call procedure manager 220 may forward the simulated runtime data received from the external caller 230 to the assembler 250. The assembler 250 may be configured to convert the simulated runtime data to ego information and return it to the simulation component 260 of the simulation system 200. For example, the assembler 250 may determine a simulated operation based on the simulated runtime data. The simulated operation may include a simulated trajectory, simulated control data, a simulated velocity profile, a simulated acceleration profile, a simulated behavior of the brake, or the like, or a combination thereof. The assembler 250 may be further configured to assess a simulation, assess an actual operation from a real road test based on a reproduced operation generated by simulation, or the like, or a combination thereof. For example, the runtime data acquired from an operation (e.g., a road test) of the autonomous vehicle including, e.g., a real trajectory; and the simulated runtime data representing a simulated operation may include a simulated trajectory; the assembler 250 may assess the simulated trajectory by comparing it with the real trajectory. More description of such an assessment may be found elsewhere in the present document. See, e.g., FIG. 5 and relevant description thereof.

The description with respect to the simulation system 200 provided above is for illustration purposes and not intended to be limiting. For example, the simulation system 200 may include or be operably coupled to one or more computer devices configured to pre-process the runtime data acquired in a road test of the autonomous vehicle before the runtime data is fed to the distiller 210. The pre-processing may include, e.g., decompression, data cleaning, data conversion, or the like, or a combination thereof. Data cleaning may include applying filters or smoothing techniques to reduce noise in sensor data (e.g., GPS or LiDAR data), identifying or eliminating data points that are significantly different from the rest of the data (which may result from, e.g., sensor errors or anomalies). Data conversion may include converting raw runtime data into a format compatible with the simulation system 200 (which may include, e.g., specific file formats or data structures). As another example, the simulation system 200 may include or be operably coupled to a display device configured to display simulation results determined by the simulation system 200. As a further example, the simulation system 200 may include user interface configured to allow user interaction with the simulation system 200. In some embodiments, the simulation system 200 may include user interface (e.g., graphics user interface (GUI)) configured to enable a user to play and view sensor data within a user-configurable time period so that the user can determine whether an algorithm for autonomous driving is performing as designed within the user configured time period.

In some embodiments, the simulation system 200 can be used as a debugging and/or error analysis tool to reconstruct or recreate virtual scenarios based on both real-world sensor data and revised algorithm for autonomous driving. The simulation system 200 can also be used to test edge cases by simulation which may be otherwise infeasible or too dangerous for a real road test. The simulation system 200 can further be used to elucidate the impact of the refresh frequency of a module on the performance of the module itself and in coordination with other modules or components in the autonomous driving system.

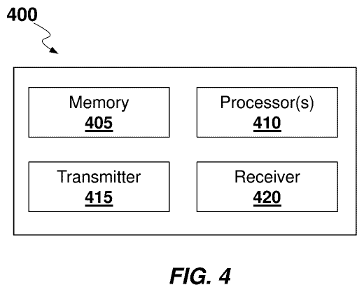

FIG. 4 illustrates an example of a hardware platform that can implement some methods and techniques described in the present document. The system 400 may include memory 405 and processor(s) 410. The memory 405 may have instructions stored thereupon. The instructions, upon execution by the processor(s) 410, may configure the system 400 (e.g., the various modules of the system 400) to perform the operations described elsewhere in the present document including, e.g., those illustrated in FIGS. 1, 3, and/or 5. The processor(s) 410 may include at least one graphics processing unit (GPU).

In some embodiments, the system 400 may include a transmitter 415 and a receiver 420 configured to send and receive information, respectively. At least one of the transmitter 415 or the receiver 420 may facilitate communication via a wired connection and/or a wireless connection between the system 400 and a device or information resource external to the system 400. For instance, the system 400 may receive runtime data acquired by various components of an autonomous vehicle during an operation of the vehicle via the receiver 420. As another example, the system 400 may receive input from a user via the receiver 420. As a further example, the system 400 may transmit a notification to a user (e.g., an autonomous vehicle, a display device) via the transmitter 415. In some embodiments, the transmitter 415 and the receiver 420 may be integrated into one communication device.

FIG. 5 illustrates a flowchart of a process for simulating an operation of an autonomous vehicle according to some embodiments of the present document. The simulation system 200, the system 300, or a portion thereof, may perform one or more operations of the process 500.

At 510, the process 500 may obtain runtime data of the operation of the autonomous vehicle. In some embodiments, the simulation system 200 may retrieve the runtime data from at least one storage device of the autonomous vehicle.

The runtime data may include first module data having a first refresh frequency and second module data having a second refresh frequency. The first module data may be acquired or determined by the first module. The second module data may be acquired or determined by the second module. For example, the autonomous vehicle may include a perception module (including, e.g., at least one sensor on the autonomous vehicle), a planning module, a detection module, a tracking module, a prediction module, a planning module, a control module, or the like, or a combination thereof, as described elsewhere in the present document. Each module of the autonomous vehicle may operate at a refresh frequency. At least two of the modules may operate at different refresh frequencies. For example, the perception module may operate at a refresh frequency of 10 Hz, and the control module may operate at a refresh frequency of 25 Hz. In some embodiments, two or more of the modules of the autonomous vehicle may operate at a same refresh frequency. For example, the perception module, the detection module, and the tracking module may all operate at a refresh frequency of 10 Hz. The runtime data may include, e.g., perception data acquired by at least one sensor of the perception module, planning data generated by the planning module, tracking data generated by the tracking module, prediction data generated by the prediction module, detection data generated by the detection module, or control data generated by the control module, or the like, or a combination thereof. Merely by way of example, the first module data may include perception data, and the second module data may include planning data. In some embodiments, the first refresh frequency may be different from the second refresh frequency.

The first module data may include a plurality of first module data units. Each of the plurality of first module data units may have a first timestamp that relates to the first refresh frequency of the first module. The first timestamp of a first module data unit may indicate a first acquisition time when data of the first data unit is acquired or determined. Similarly, the second module data may include a plurality of second module data units. Each of the plurality of second module data units may have a second timestamp that relates to the second refresh frequency of the second module. The second timestamp of a second module data unit may indicate a second acquisition time when data of the second data unit is acquired or determined.

The runtime data (also referred to as log data) may include respective first timestamps for the plurality of first module data units and respective second timestamps for the plurality of second module data units. The simulation system 200 may arrange the first module data by dividing, based on the log data, the first module data into the plurality of first module data units; and arrange the second module data by dividing, based on the log data, the second module data into the plurality of second module data units. The simulation system 200 may label the first module data units with the first timestamps and label the second module data units with the second timestamps. In some embodiments, the labeling may be performed as part of pre-processing.

In some embodiments, a timestamp of a data unit (e.g., a first module data unit, a second module data unit) may deviate from an expected or ideal time data of the data unit should have been acquired or generated based on the refresh frequency. Such a deviation may be due to, e.g., a delay in the transmission of the data to or within the simulation system 200 (e.g., sensor data from a sensor where the sensor data is acquired to the corresponding storage in the perception module, or a downstream module), a glitch in processing the data (e.g., a glitch in data processing in the control module), or the like, or a combination thereof. Such deviation may be recorded in the timestamp and also the runtime data (e.g., the log data).

At 520, the process 500 may include compiling a plurality of simulation data packets based on the runtime data according to a simulation frequency. The simulation data packets may constitute simulated runtime data. The simulation frequency may be different from at least one of the first refresh frequency or the second refresh frequency. Each of the plurality of simulation data packets may correspond to a simulation timestamp that relate to the simulation frequency and indicates a sampling time. In some embodiments, the simulation system 200 may receive, e.g., via a user interface, a user instruction regarding the simulation frequency and configure the simulation frequency based on the user instruction.

Each of the plurality of simulation data packets may include or relate to a first module data unit corresponding to a first timestamp and a second module data unit corresponding to a second timestamp. For a simulation data packet, a first time interval between the first timestamp (or the first acquisition time) of the first module data unit and the sampling time may be below a first threshold relating to the first refresh frequency; a second time interval between the second timestamp (or the second acquisition time) of the second module data unit and the sampling time may be below a second threshold relating to the second refresh frequency. In some embodiments, the first threshold may be or otherwise relate to an inverse of the first refresh frequency. In some embodiments, the second threshold may be or otherwise relate to an inverse of the second refresh frequency.

To compile a simulation data packet, the simulation system 200 may identify, from the plurality of first module data units, a first module data unit based on the sampling time of the simulation data packet, and identify, from the plurality of second module data units, a second module data unit based on the sampling time of the simulation data packet. The identified first module data unit may have a first timestamp that is no later than the sampling time. The identified second module data unit may have a second timestamp that is no later than the sampling time. For example, the identified first module data unit may have a first timestamp that is no later than and closest to the sampling time among the plurality of first module data units. As another example, the identified second module data unit may have a second timestamp that is no later than and closest to the sampling time among the plurality of second module data units. See, e.g., relevant description of the temporal call procedure manager 220, as well as FIGS. 3A through 3D and relevant description thereof, which is not repeated here.

The simulation system 200 may process one or more of the data units of a simulation data packet using an applicable processing algorithm. For example, the simulation system 200 may retrieve a first processing algorithm configured to process the first module data and a second processing algorithm configured to process the second module data, and generate the plurality of simulation data packets based on the first module data, the second module data, the first processing algorithm, and the second processing algorithm. Specifically, the simulation system 200 may, for each of the plurality of simulation data packets, determine a processed first module data unit by processing, using the first processing algorithm, a first module data unit of the simulation data packet, and determine a processed second module data unit by processing, using the second processing algorithm, a second module data unit of the simulation data packet. After the processing, a simulation data packet may include a processed first module data unit and a processed second module data unit. In some embodiments, a simulation data packet may include initial first and module data units, in addition to the processed first and second module data units.

At 530, the process 500 may include simulating the operation of the autonomous vehicle over time based on the plurality of simulation data packets. The simulation system 200 may determine a simulated operation based on the simulated runtime data including the plurality of simulation data packets. The simulation system 200 may analyze or replay the operation, including performance of various components of the autonomous vehicle during the operation, based on the simulated operation. The simulation system 200 may assess the simulation by comparing the simulated operation (e.g., the simulated runtime data) with the actual operation recorded in the runtime data. The simulation system 200 may adjust one or more aspects of the simulation including, e.g., the simulation frequency, the first refresh frequency, the second refresh frequency, a processing algorithm, or the like, or a combination, based on the assessment.

For example, the runtime data of the actual operation of the autonomous vehicle may include a real trajectory of the autonomous vehicle during the operation, the simulated operation of the autonomous vehicle may include a simulated trajectory; the simulation system 200 may assess the simulation by comparing the real trajectory and the simulated trajectory. As another example, the simulated runtime data may include simulated control data generated based on a control simulation algorithm; the simulation system 200 may assess the control simulation algorithm by comparing the simulated operation with the operation. Merely by way of example, the simulation system 200 may assess the control simulation algorithm by comparing the control data and the simulated control data, or comparing a simulated trajectory estimated based on the simulated control data with a real trajectory recorded in the runtime data, or comparing simulated performance of the engine module (powertrain, brake, etc.) with the performance of the engine module in the actual operation. As a further example, the simulation system 200 may assess the simulated operation by comparing the simulated operation with a performance metrics. Examples of performance metrics may include occurrence of emergency maneuver, smoothness of brake events, fuel efficiency, trip time, energy consumption, object detection accuracy, localization accuracy, or the like, or a combination thereof.

Based on an assessment, the simulation system 200 may adjust one or more aspects of the simulation procedure or the simulation system 200. For example, based on an assessment, the simulation system 200 may adjust at least one of a first processing algorithm configured to process the first module data, a second processing algorithm configured to process the second module data, the first refresh frequency, the second refresh frequency, the simulation frequency, or a simulation algorithm configured to simulate the operation of the autonomous vehicle over time based on the plurality of simulation data packets. For example, based on an assessment, the simulation system 200 may replace at least one of the first processing algorithm, the second processing algorithm, or the simulation algorithm with a different version (e.g., a newer version, a debugged version) thereof. As another example, based on an assessment, the simulation system 200 may generate an adjusted first refresh frequency, on the basis of which the simulation system 200 may generate adjusted first module data units with adjusted timestamps. The simulation system 200 may repeat the process 500, or a portion thereof, based on the adjustment, and assess the impact of the adjustment on the performance of the autonomous vehicle, and/or on the simulation process 500.

In some embodiments, the simulation system 200 can perform the process 500 to implement a debugging and/or error analysis tool to reconstruct or recreate virtual scenarios based on real-world sensor data and synthesized driving environment and/or revised algorithms for autonomous driving. For example, at least a portion of the runtime data of an operation of the autonomous vehicle may be synthesized by, e.g., specifying an operation parameter of the autonomous vehicle, the behavior of an NPC, the road condition, the traffic condition, or the like, or a combination thereof. Examples of operation parameters of the autonomous vehicle that can be configured for simulation via the simulation system 200 include the first refresh frequency of the first module, the second refresh frequency of the second module, the simulation frequency, the first processing algorithm, the second processing algorithm, etc. Merely by way of example, based on runtime data acquired from a real road test, the simulation system 200 may obtain the first module data units with timestamps, and add a random delay (e.g., by adding a 5% or 10% delay) to one or more of the plurality of first module data units, and estimate the impact of this random delay on the operation of the autonomous vehicle (e.g., by performing the process 500 as illustrated in FIG. 5).

In some embodiments, the simulation system 200 can perform the process 500 to implement a test to delineate the impact of a refresh frequency associated with a module (e.g., a software module (e.g., a detection algorithm for the detection module, a tracking algorithm for the tracking module, an image processing algorithm for processing sensor data acquired by one sensor) in the software stack of multiple software modules of the autonomous vehicle) on the behavior of autonomous vehicle. For example, a user may set different combinations of the refresh frequencies for the first module and the second module, and keep other portions of the simulation constant; the simulation system 200 may repeat the process 500 based on the same runtime data (e.g., synthesized or acquired from a real road test) and the set refresh frequencies, and generated simulated operations of the autonomous vehicle, and assess the impact of the refresh frequencies by comparing the simulated operations.

In some embodiment, the process 500 may further include causing at least a portion of the operation or the simulated operation, or data input to or processed by the simulation system 200 when performing the process 500. For example, the simulation system 200 may cause the simulated operation to be displayed on a display device. The simulation system 200 may receive, e.g., via a user interface, a user input, and cause at least one of the simulated operation or the operation to be displayed according to the user input. The user may specify in the user input, e.g., a replay speed, a time window of the simulated operation or the operation to be displayed, looping, pausing replay, or superimposing the simulated operation and the operation for display. For example, the simulation system 200 may superimpose, for convenient visual comparison, a simulated trajectory and the real trajectory, a simulated velocity profile and the real velocity profile, a simulated acceleration profile and the real acceleration profile, a simulated brake pressure profile and a real brake pressure profile, etc. The simulation system 200 may cause simulated runtime data and/or the real runtime data to be displayed in the form of a curve, a video, an image, a table, text, or the like, or a combination thereof.

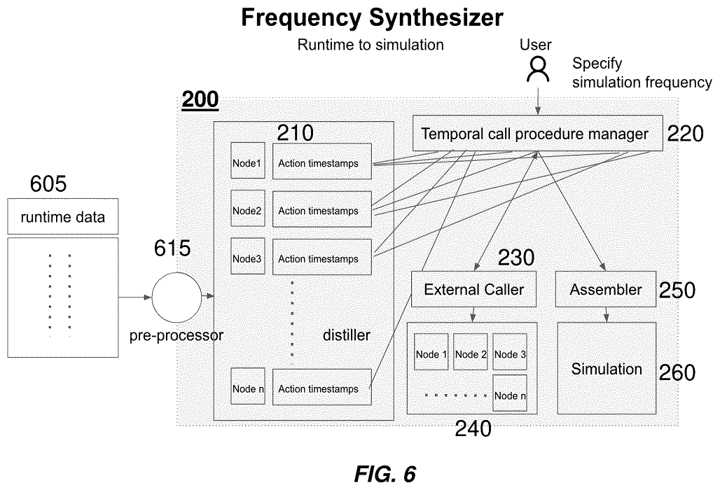

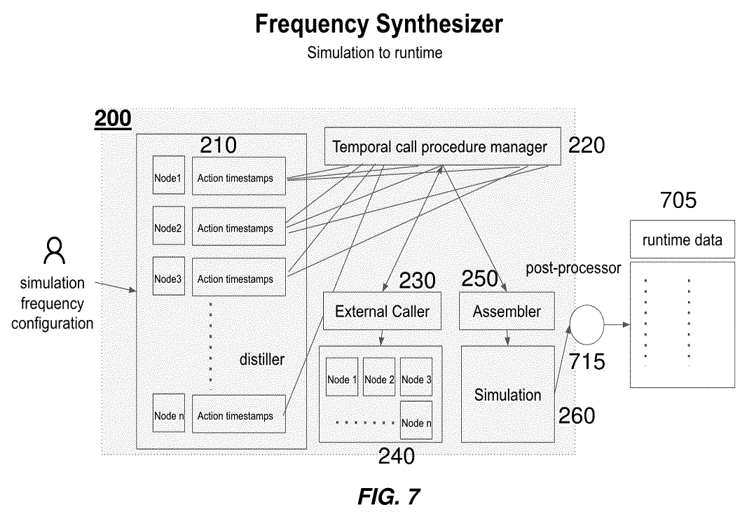

FIGS. 6 and 7 illustrate use cases of the simulation technology according to some embodiments of the present document. FIG. 6 illustrates a use case in which a real life (RL) vehicle (RL ego) operating on a RL road stores log data in a vehicle log (the “runtime data 605” in FIG. 6). A pre-processor 615 may pre-process and feed the runtime data 605 to the distiller 210. Examples of pre-processing may be found elsewhere in the present document, and not repeated here. A simulation may be performed based on a simulation frequency to replay the vehicle log data. During, e.g., validation testing or debugging, the simulation may be performed to check whether the simulated ego (“sim ego”) behaves properly across the range of conditions found in the vehicle logs. The vehicle logs can include sensor data, control commands to the steering and engine, and outputs from the software modules that make up the ego software, including perception, tracking, prediction, planning, and control. The simulation frequency may be specified by a user and provided to the simulation system 200 via a user interface.

FIG. 7 illustrates a use case in which simulation can be used to “try out” a new software or software feature on a sim ego before the new software or software feature is used on an RL ego. Examples of such software may include any one of the processing algorithms 240-1 through 240-M as illustrated in FIG. 2, a simulation algorithm to generate control data (based on data including perception data, planning data, etc.), the refresh frequency of any one of the modules that is configured to acquire or determine data involved in the operation of the RL ego, the simulation frequency, etc. Even if the RL ego is in a lab or on a test track, new features may be too immature, unstable, unpredictable, or risky to people, equipment, and infrastructure. By testing the new feature on a sim ego, the suer (e.g., a developer) can drive the sim ego through the desired behavior or scenarios without the risk of personal injury or property damage. During this example use case, the simulation system 200 may record the behavior of the sim ego and store it in a simulated vehicle log. The sim vehicle log can be used like any other vehicle log as described in the present document including, the process 500, the use case as illustrated in FIG. 6, etc. The user may specify various simulation frequency configurations including various simulation frequency, and/or refresh frequencies of a module on the basis of which simulation may be performed (e.g., by repeating process 500 for each of the simulation frequency configuration). The simulation result may be processed using a post-processor 715 and reproduced as simulated runtime data 705. Based on the simulation results, the simulation system 200 or the user may assess the new software or software feature and determine whether it is satisfactory or optimized.

In some embodiments, the simulation system 200 may be configured to obtain or synthesize runtime data, or a portion thereof. The simulation system 200 may synthesize at least a portion of the runtime data based on a synthesis algorithm. For example, the simulation system 200 may receive a user instruction relating to at least one of the first refresh frequency, the second refresh frequency, or the simulation frequency, and synthesize at least a portion of the runtime data by configuring at least one of the first refresh frequency, the second refresh frequency, or the simulation frequency based on the user instruction. As another example, the simulation system 200 may simulate one or more scenarios (e.g., driving behavior of each of one or more NPCs) for the driving environment in which the autonomous vehicle is to traverse and simulate operations of the autonomous vehicle in response. The simulation system 200 may also simulate extraordinary or edge cases and simulate the operation of the autonomous vehicle in such cases. For example, the simulation system 200 may simulate cases in which one or more components of the autonomous vehicle malfunction or fail, or there is a dangerous road condition or traffic condition, and simulate the operation of the autonomous vehicle to make improvements (e.g., by designing redundancies) to increase the safety and/or robustness of the autonomous driving system of the vehicle. The simulation system 200 may reproducibly simulate the operation of the autonomous vehicle and allow a great flexibility in configuring the simulation procedure, and therefore offering reliability and versatility in simulating autonomous vehicle operations, as well as other events, which are represented by asynchronized data.

Some example technical solutions are implemented as described below.

1. A method for simulating an operation of an autonomous vehicle over time, comprising: obtaining runtime data of the operation of the autonomous vehicle (AV) during the operation, the runtime data including first module data having a first refresh frequency and second module data having a second refresh frequency, wherein: the first module data includes a plurality of first module data units, each of the plurality of first module data units having a first timestamp that relates to the first refresh frequency and indicates a first acquisition time; and the second module data includes a plurality of second module data units, each of the plurality of second module data units having a second timestamp that relates to the second refresh frequency and indicates a second acquisition time; compiling a plurality of simulation data packets based on the runtime data according to a simulation frequency that is different from at least one of the first refresh frequency or the second refresh frequency, wherein each of the plurality of simulation data packets comprises or relates to: a simulation timestamp that relates to the simulation frequency and indicates a sampling time; a first module data unit corresponding to a first timestamp, a first time interval between the first acquisition time and the sampling time being below a first threshold relating to the first refresh frequency; and a second module data unit corresponding to a second timestamp, a second time interval between the second acquisition time and the sampling time being below a second threshold relating to the second refresh frequency; and simulating the operation of the autonomous vehicle over time based on the plurality of simulation data packets.

2. The method of one or more of the examples herein, wherein compiling the plurality of simulation data packets comprises: retrieving a first processing algorithm configured to process the first module data and a second processing algorithm configured to process the second module data; and generating the plurality of simulation data packets based on the first module data, the second module data, the first processing algorithm, and the second processing algorithm.

3. The method of one or more of the examples herein, wherein: each of the plurality of simulation data packets comprises a processed first module data unit and a processed second module data unit; and generating the plurality of simulation data packets based on the first module data, the second module data, the first processing algorithm, and the second processing algorithm comprises: for each of the plurality of simulation data packets, determining a processed first module data unit by processing, using the first processing algorithm, a first module data unit of the simulation data packet; and determining a processed second module data unit by processing, using the second processing algorithm, a second module data unit of the simulation data packet.

4. The method of one or more of the examples herein, wherein compiling the plurality of simulation data packets comprises: for each of the plurality of simulation data packets, identifying, from the plurality of first module data units, a first module data unit based on the sampling time of the simulation data packet, wherein the identified first module data unit has a first timestamp that is no later than the sampling time; and identifying, from the plurality of second module data units, a second module data unit based on the sampling time of the simulation data packet, wherein the identified second module data unit has a second timestamp that is no later than the sampling time.

5. The method of one or more of the examples herein, wherein for each of the plurality of simulation data packets, identifying a first module data unit comprises identifying, among the plurality of first module data units, the first module data unit having a first timestamp that is no later than and closest to the sampling time; and identifying a second module data unit comprises identifying, among the plurality of second module data units, the second module data unit having a second timestamp that is no later than and closest to the sampling time.

6. The method of one or more of the examples herein, wherein for two simulation data packets corresponding to two consecutive sampling times, first module data units of the two simulation data packets have a same first timestamp; and second module data units of the two simulation data packets have a same second timestamp.

7. The method of one or more of the examples herein, wherein for two simulation data packets corresponding to two consecutive sampling times, first module data units of the two simulation data packets have a same first timestamp; and second module data units of the two simulation data packets have different second timestamps.

8. The method of one or more of the examples herein, wherein for two simulation data packets corresponding to two consecutive sampling times, first module data units of the two simulation data packets have different first timestamps; and second module data units of the two simulation data packets have different second timestamps.

9. The method of one or more of the examples herein, wherein: the first threshold relates to an inverse of the first refresh frequency; or the second threshold relates to an inverse of the second refresh frequency.

10. The method of one or more of the examples herein, further comprising: receiving a user instruction regarding the simulation frequency; and setting the simulation frequency based on the user instruction.

11. The method of one or more of the examples herein, wherein at least one of the first module data or the second module data comprises perception data acquired by at least one sensor on the autonomous vehicle, planning data generated by a planning module of the autonomous vehicle, tracking data generated by a tracking module of the autonomous vehicle, prediction data generated by a prediction module, detection data generated by a detection module, or control data generated by a control module.

12. The method of one or more of the examples herein, wherein: the first module data comprises perception data; the second module data comprises planning data; the runtime data further comprises one or more of: tracking data having a tracking data refresh frequency; prediction data having a prediction data refresh frequency; detection data having a detection data refresh frequency; or control data having a control data refresh rate; and the method further comprises simulating the operation based further on at least one of the tracking data, the detection data, the prediction data, or the prediction data.

13. The method of one or more of the examples herein, further comprising assessing the simulated operation.

14. The method of one or more of the examples herein, wherein assessing the simulated operation comprises comparing the simulated operation with the operation recorded in the runtime data.

15. The method of one or more of the examples herein, wherein assessing the simulated operation comprises comparing the simulated operation with a performance metrics.

16. The method of one or more of the examples herein, wherein: the runtime data comprises a real trajectory of the autonomous vehicle during the operation; the simulated operation of the autonomous vehicle comprises a simulated trajectory; and assessing the simulated operation comprises comparing the real trajectory and the simulated trajectory.

17. The method of one or more of the examples herein, wherein: simulating the operation comprises simulating control data based on a control simulation algorithm; and assessing the simulated operation comprises assessing the control simulation algorithm.

18. The method of one or more of the examples herein, wherein assessing the control simulation algorithm comprises at least one of: comparing the control data and the simulated control data; or comparing a simulated trajectory estimated based on the simulated control data with a real trajectory recorded in the runtime data.

19. The method of one or more of the examples herein, further comprising: based on the assessment, adjusting at least one of a first processing algorithm configured to process the first module data, a second processing algorithm configured to process the second module data, the first refresh frequency, the second refresh frequency, the simulation frequency, or a simulation algorithm configured to simulate the operation of the autonomous vehicle over time based on the plurality of simulation data packets; and simulating the operation of the autonomous vehicle based on the adjustment.

20. The method of one or more of the examples herein, wherein adjusting at least one of the first processing algorithm, the second processing algorithm, the first refresh frequency, the second refresh frequency, the simulation frequency, or the simulation algorithm comprises: replacing at least one of the first processing algorithm, the second processing algorithm, or the simulation algorithm with a different version thereof.

21. The method of one or more of the examples herein, wherein: the adjustment comprises an adjusted first refresh frequency; and simulated runtime data corresponding to the simulated operation generated based on the adjustment comprises adjusted first module data including a plurality of adjusted first module data units, each of which has an updated first timestamp corresponding to the adjusted first refresh frequency.

22. The method of one or more of the examples herein, wherein obtaining the runtime data comprising retrieving the runtime data from at least one storage device of the autonomous vehicle.

23. The method of one or more of the examples herein, wherein obtaining the runtime data comprising: synthesizing at least a portion of the runtime data based on a synthesis algorithm.

24. The method of one or more of the examples herein, further comprising receiving a user instruction relating to at least one of the first refresh frequency, the second refresh frequency, or the simulation frequency, wherein synthesizing at least a portion of the runtime data comprises configuring at least one of the first refresh frequency, the second refresh frequency, or the simulation frequency based on the user instruction.

25. The method of one or more of the examples herein, wherein the runtime data comprises log data that includes respective first timestamps for the plurality of first module data units and respective second timestamps for the plurality of second module data units.

26. The method of one or more of the examples herein, wherein: arranging the first module data comprises dividing, based on the log data, the first module data into the plurality of first module data units; and arranging the second module data comprises dividing, based on the log data, the second module data into the plurality of second module data units.

27. The method of one or more of the examples herein, wherein the first refresh frequency is different from the second refresh frequency.

28. The method of one or more of the examples herein, wherein the runtime data is asynchronous.

29. The method of one or more of the examples herein, further comprising pre-processing the runtime data including: labeling each of the plurality of first module data units with the respective first timestamps; and labeling each of the plurality of second module data units with the respective second timestamps.

30. The method of one or more of the examples herein, further comprising: causing the simulated operation to be displayed on a display device.

31. The method of one or more of the examples herein, further comprising: receiving a user input; and causing at least one of the simulated operation or the operation to be displayed according to the user input.

32. The method of one or more of the examples herein, wherein the user input comprises a replay speed, a time window of the simulated operation or the operation to be displayed, looping, pausing replay, or superimposing the simulated operation and the operation for display.

33. A method for simulating an event over time, comprising: obtaining runtime data of the event, the runtime data including first module data having a first refresh frequency and second module data having a second refresh frequency, wherein: the first module data comprises a plurality of first module data units, each of the plurality of first module data units having a first timestamp that relates to the first refresh frequency and indicates a first acquisition time; and the second module data comprises a plurality of second module data units, each of the second module data units having a timestamp that relates to the second refresh frequency and indicates a second acquisition time; compiling, based on the runtime data, a plurality of simulation data packets according to a simulation frequency that is different from at least one of the first refresh frequency or the second refresh frequency, wherein each of the plurality of simulation data packets comprises or relates to: a simulation timestamp that relates to the simulation frequency and indicates a sampling time; a first module data unit corresponding to a first timestamp, a first time interval between the first timestamp and the sampling time being below a first threshold relating to the first refresh frequency; and a second module data unit corresponding to a second timestamp, a second time interval between the second timestamp and the sampling time being below a second threshold relating to the second refresh frequency; and simulating the event over time based on the plurality of simulation data packets.

In some embodiments, the first refresh frequency is different from the second refresh frequency. In some embodiments, the runtime data is asynchronous.

34. A system for simulating an operation of an autonomous vehicle over time, comprising: memory storing computer program instructions; and one or more processors configured to execute the computer program instructions to effectuate the method of one or more of the examples herein.

35. A system for simulating an operation of an autonomous vehicle over time, comprising: a distiller module configured to: receive runtime data, the runtime data comprising first module data having a first refresh frequency and second module data acquired at a second refresh frequency, wherein the first module data comprises a plurality of first module data units, each of the plurality of first module data units having a timestamp that relates to the first refresh frequency and indicates a first acquisition time when the first module data unit was acquired; and the second module data comprises a plurality of second module data units, each of the second module data units having a timestamp that relates to the second refresh frequency and indicates a second acquisition time when the second module data unit was acquired; a temporal call procedure manager configured to compile, based on the runtime data, a plurality of simulation data packets according to a simulation frequency that is different from at least one of the first refresh frequency or a second refresh frequency, wherein each of the plurality of simulation data packets comprises or relates to: a timestamp that relates to the simulation frequency and indicates a sampling time; a first module data unit corresponding to a first timestamp, a first time interval between the first timestamp and the sampling time being below a first threshold relating to the first refresh frequency; and a second module data unit corresponding to a second timestamp, a second time interval between the second timestamp and the sampling time being below a second threshold relating to the second refresh frequency; and an assembler configured to simulate the operation of the autonomous vehicle over time based on the plurality of simulation data packets.

36. The system of one or more of the examples herein, further comprising an external caller configured to provide to the temporal call procedure manager a processing algorithm for processing the first module data or the second module data.

37. The system of one or more of the examples herein, further comprising a user interface configured to receive a user instruction for configuring at least one of the first refresh frequency, the second refresh frequency, or the simulation frequency.

38. The system of one or more of the examples herein, further comprising or being operably coupled to a display device configured to replay at least one of the simulated operation or the operation of the autonomous vehicle.

39. The system of one or more examples herein, further comprising a user interface configured to receive a user instruction for configuring at least one of the first refresh frequency, the second refresh frequency, or the simulation frequency.

40. The system of one or more examples herein, further comprising or being operably coupled to a display device configured to replay at least one of the simulated operation or the operation of the autonomous vehicle.

Implementations of the subject matter and the functional operations described in this patent document can be implemented in various systems, digital electronic circuitry, or in computer software, firmware, or hardware, including the structures disclosed in this specification and their structural equivalents, or in combinations of one or more of them. Implementations of the subject matter described in this specification can be implemented as one or more computer program products, e.g., one or more modules of computer program instructions encoded on a tangible and non-transitory computer readable medium for execution by, or to control the operation of, data processing apparatus. The computer readable medium can be a machine-readable storage device, a machine-readable storage substrate, a memory device, a composition of matter effecting a machine-readable propagated signal, or a combination of one or more of them. The term “data processing unit” or “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

Processors suitable for the execution of a computer program include, by way of example, both general and special purpose microprocessors, and any one or more processors of any kind of digital computer. Generally, a processor will receive instructions and data from a read only memory or a random-access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of nonvolatile memory, media and memory devices, including by way of example semiconductor memory devices, e.g., EPROM, EEPROM, and flash memory devices. The processor and the memory can be supplemented by, or incorporated in, special purpose logic circuitry.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments. Only a few implementations and examples are described, and other implementations, enhancements and variations can be made based on what is described and illustrated in this patent document.

1. A method for simulating an operation of an autonomous vehicle over time, comprising:
obtaining runtime data of the operation of the autonomous vehicle (AV) during the operation, the runtime data including first module data having a first refresh frequency and second module data having a second refresh frequency, wherein:
the first module data includes a plurality of first module data units, each of the plurality of first module data units having a first timestamp that relates to the first refresh frequency and indicates a first acquisition time; and
the second module data includes a plurality of second module data units, each of the plurality of second module data units having a second timestamp that relates to the second refresh frequency and indicates a second acquisition time;
compiling a plurality of simulation data packets based on the runtime data according to a simulation frequency that is different from at least one of the first refresh frequency or the second refresh frequency, wherein each of the plurality of simulation data packets comprises or relates to:
a simulation timestamp that relates to the simulation frequency and indicates a sampling time;
a first module data unit corresponding to a first timestamp, a first time interval between the first acquisition time and the sampling time being below a first threshold relating to the first refresh frequency; and
a second module data unit corresponding to a second timestamp, a second time interval between the second acquisition time and the sampling time being below a second threshold relating to the second refresh frequency; and
simulating the operation of the autonomous vehicle over time based on the plurality of simulation data packets.

2. The method of claim 1, wherein compiling the plurality of simulation data packets comprises:
retrieving a first processing algorithm configured to process the first module data and a second processing algorithm configured to process the second module data; and
generating the plurality of simulation data packets based on the first module data, the second module data, the first processing algorithm, and the second processing algorithm.

3. The method of claim 2, wherein:
each of the plurality of simulation data packets comprises a processed first module data unit and a processed second module data unit; and
generating the plurality of simulation data packets based on the first module data, the second module data, the first processing algorithm, and the second processing algorithm comprises: for each of the plurality of simulation data packets,
determining a processed first module data unit by processing, using the first processing algorithm, a first module data unit of the simulation data packet; and
determining a processed second module data unit by processing, using the second processing algorithm, a second module data unit of the simulation data packet.

4. The method of claim 1, wherein compiling the plurality of simulation data packets comprises: for each of the plurality of simulation data packets,
identifying, from the plurality of first module data units, a first module data unit based on the sampling time of the simulation data packet, wherein the identified first module data unit has a first timestamp that is no later than the sampling time; and
identifying, from the plurality of second module data units, a second module data unit based on the sampling time of the simulation data packet, wherein the identified second module data unit has a second timestamp that is no later than the sampling time.

5. The method of claim 4, wherein for each of the plurality of simulation data packets,
identifying a first module data unit comprises identifying, among the plurality of first module data units, the first module data unit having a first timestamp that is no later than and closest to the sampling time; and
identifying a second module data unit comprises identifying, among the plurality of second module data units, the second module data unit having a second timestamp that is no later than and closest to the sampling time.

6. The method of claim 1, wherein for two simulation data packets corresponding to two consecutive sampling times,
first module data units of the two simulation data packets have a same first timestamp; and
second module data units of the two simulation data packets have a same second timestamp.

7. The method of claim 1, wherein for two simulation data packets corresponding to two consecutive sampling times,
first module data units of the two simulation data packets have a same first timestamp; and
second module data units of the two simulation data packets have different second timestamps.

8. The method of claim 1, wherein for two simulation data packets corresponding to two consecutive sampling times,
first module data units of the two simulation data packets have different first timestamps; and
second module data units of the two simulation data packets have different second timestamps.

9. The method of claim 1, wherein;
the first threshold relates to an inverse of the first refresh frequency; or
the second threshold relates to an inverse of the second refresh frequency.

10. The method of claim 1, wherein at least one of the first module data or the second module data comprises perception data acquired by at least one sensor on the autonomous vehicle, planning data generated by a planning module of the autonomous vehicle, tracking data generated by a tracking module of the autonomous vehicle, prediction data generated by a prediction module, detection data generated by a detection module, or control data generated by a control module.

11. The method of claim 1, wherein:
the first module data comprises perception data;
the second module data comprises planning data;
the runtime data further comprises one or more of:
tracking data having a tracking data refresh frequency;
prediction data having a prediction data refresh frequency;
detection data having a detection data refresh frequency; or
control data having a control data refresh rate; and
the method further comprises simulating the operation based further on at least one of the tracking data, the detection data, the prediction data, or the prediction data.

12. The method of claim 1, further including assessing the simulation, wherein:
the runtime data comprises a real trajectory of the autonomous vehicle during the operation;
the simulated operation of the autonomous vehicle comprises a simulated trajectory; and
assessing the simulated operation comprises comparing the real trajectory and the simulated trajectory.

13. The method of claim 12, further comprising:
based on the assessment, adjusting at least one of a first processing algorithm configured to process the first module data, a second processing algorithm configured to process the second module data, the first refresh frequency, the second refresh frequency, the simulation frequency, or a simulation algorithm configured to simulate the operation of the autonomous vehicle over time based on the plurality of simulation data packets; and
simulating the operation of the autonomous vehicle based on the adjustment.

14. A method for simulating an event over time, comprising:
obtaining runtime data of the event, the runtime data including first module data having a first refresh frequency and second module data having a second refresh frequency, wherein:
the first module data comprises a plurality of first module data units, each of the plurality of first module data units having a first timestamp that relates to the first refresh frequency and indicates a first acquisition time; and
the second module data comprises a plurality of second module data units, each of the second module data units having a timestamp that relates to the second refresh frequency and indicates a second acquisition time;
compiling, based on the runtime data, a plurality of simulation data packets according to a simulation frequency that is different from at least one of the first refresh frequency or the second refresh frequency, wherein each of the plurality of simulation data packets comprises or relates to:
a simulation timestamp that relates to the simulation frequency and indicates a sampling time;
a first module data unit corresponding to a first timestamp, a first time interval between the first timestamp and the sampling time being below a first threshold relating to the first refresh frequency; and
a second module data unit corresponding to a second timestamp, a second time interval between the second timestamp and the sampling time being below a second threshold relating to the second refresh frequency; and
simulating the event over time based on the plurality of simulation data packets.

15. The method of claim 11, wherein the first refresh frequency is different from the second refresh frequency.

16. The method of claim 11, wherein the runtime data is asynchronous.

17. A system for simulating an operation of an autonomous vehicle over time, comprising:
a distiller module configured to:
receive runtime data, the runtime data comprising first module data having a first refresh frequency and second module data acquired at a second refresh frequency, wherein
the first module data comprises a plurality of first module data units, each of the plurality of first module data units having a timestamp that relates to the first refresh frequency and indicates a first acquisition time when the first module data unit was acquired; and
the second module data comprises a plurality of second module data units, each of the second module data units having a timestamp that relates to the second refresh frequency and indicates a second acquisition time when the second module data unit was acquired;
a temporal call procedure manager configured to compile, based on the runtime data, a plurality of simulation data packets according to a simulation frequency that is different from at least one of the first refresh frequency or a second refresh frequency, wherein each of the plurality of simulation data packets comprises or relates to:
a timestamp that relates to the simulation frequency and indicates a sampling time;
a first module data unit corresponding to a first timestamp, a first time interval between the first timestamp and the sampling time being below a first threshold relating to the first refresh frequency; and
a second module data unit corresponding to a second timestamp, a second time interval between the second timestamp and the sampling time being below a second threshold relating to the second refresh frequency; and
an assembler configured to simulate the operation of the autonomous vehicle over time based on the plurality of simulation data packets.

18. The system of claim 17, further comprising an external caller configured to provide to the temporal call procedure manager a processing algorithm for processing the first module data or the second module data.

19. The system of claim 17, further comprising a user interface configured to receive a user instruction for configuring at least one of the first refresh frequency, the second refresh frequency, or the simulation frequency.

20. The system of claim 17, further comprising or being operably coupled to a display device configured to replay at least one of the simulated operation or the operation of the autonomous vehicle.
